(19) United States
(12) Patent Application Publication
(10) Pub. No.: US 2014/0307391 A1
(43) Pub. Date: Oct. 16, 2014

(54) THREE DIMENSIONAL PACKAGING

(71) Applicant: INFINEON TECHNOLOGIES AG, NEUBIBERG (DE)

(72) Inventor: Martin STANDING, Villach (AT)

(73) Assignee: Infineon Technologies AG, NEUBIBERG (DE)

(21) Appl. No.: 13/862,400

(22) Filed: Apr. 13, 2013

(51) Int. Cl. H05K 1/18; H05K 3/30

(52) U.S. Cl. CPC H05K 1/189; H05K 3/30; H05K 3/306
USPC 361/720; 174/254; 361/749; 361/761; 29/829; 29/832; 29/834

(57) ABSTRACT

Representative implementations of devices and techniques provide a printed circuit board (PCB) arranged to at least partly surround an electrical component having a plurality of non-coplanar outer surfaces. The PCB is arranged to fold at one or more predetermined boundaries.

### BACKGROUND

As modern technology shrinks the size of electronic devices, board space for circuits and systems (such as power supplies, for example) likewise decreases. However, in many cases, the requirements (such as power output, for example) of the circuits and systems do not decrease proportionately. This means that a modern circuit or system generally has a lesser area (or footprint) to work with than earlier generations, and it has an equal or greater output requirement per unit area.

Advantages may be gained by compacting portions of electronic devices, such as integrating control circuits with the circuits or systems being controlled. However, this can be problematic, placing an even greater demand on board space to accommodate the control circuits and their associated support components. This may be particularly challenging when many of the support components are larger discrete components, such as discrete passive devices, for example.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternately, other implementations of devices and/or systems may include additional components, or various combinations of the described components, and remain within the scope of the disclosure.

FIG. 1 is a perspective view of an example 3D packaging arrangement including an electrical component, a PCB, an IC chip die and other discrete circuit components, prior to folding the PCB, according to an implementation.

FIG. 2 illustrates two perspective views of the example 3D packaging arrangement of FIG. 1, after folding the PCB, according to an implementation. A topside view and an underside view of the 3D arrangement are shown.

FIG. 3 is a profile view of the example 3D packaging arrangement of FIG. 1, showing example components embedded within the PCB and example components mounted to surfaces of the PCB, according to an implementation. FIG. 3 also shows an example foldable PCB in a flat (unfolded) configuration, according to an implementation.

FIG. 4 is a flow diagram illustrating an example process for folding a printed circuit board (PCB), according to an implementation.

### DETAILED DESCRIPTION

### Overview

Techniques of three dimensional packaging are disclosed for incorporating multiple components, circuits, and/or systems onto a minimized footprint. For example, within roughly the same board space used for the footprint of an electrical component (an inductor, for example), a circuit or system may also be located. In many implementations, the circuit or system includes the electrical component, resulting in various performance advantages in addition to conserving board area.

Representative implementations of devices and techniques provide a foldable printed circuit board (PCB) arranged to at least partly surround an electrical component. In an implementation, the PCB is arranged to fold at one or more predetermined boundaries. For example, the PCB may fold at the predetermined boundaries to partly or fully surround the electrical component.

In some implementations, the electrical component has a plurality of non-coplanar outer surfaces. In an implementation, the PCB folds such that portions (e.g., planes of the portions) of the PCB are parallel with non-coplanar surfaces of the electrical component. In various implementations, some or all of the portions of the PCB may be coupled to the surfaces of the electrical component.

In an implementation, one or more electrical devices are mounted onto or embedded within the PCB. For example, the PCB may be comprised of multiple layers. The electrical devices may be part of a circuit or system that includes the PCB and the electrical component.

In various implementations, the electrical component is a passive component such as an inductor, resistor, capacitor, a transformer, a heat sink, a choke, or the like. In an implementation, an integrated circuit (IC) chip die may be mounted onto or embedded within the PCB. In some implementations, the passive component may be electrically coupled to the chip die, or to other electrical devices. For example, the passive component may conduct electrical current as part of an electrical circuit that includes circuit components formed on the chip die. The electrical current may pass through the passive component as well as through portions of circuit components or circuits formed on the chip die, or other electrical devices mounted onto or embedded within the PCB.

In another implementation, the passive component may be placed or positioned such that portions of the passive component overlap portions of the chip die or other electrical devices. For example, electrical contacts or terminals of the passive component may overlap contact areas of the chip die or other electrical devices. In alternate implementations, the passive component may be strategically or deliberately placed or positioned to optimize cooling of the chip die or other electrical devices. In one example, the passive component is located such that it forms a thermal capacitance with respect to the chip die or other electrical devices. In another example, the passive component is located such that it forms a heat sink with respect to the chip die or other electrical devices.

Various implementations and arrangements are discussed with reference to electrical and electronics components and varied carriers. While specific components (i.e., integrated circuit chip dice, resistors, capacitors, inductors, chokes, etc.) are mentioned, this is not intended to be limiting, and is for ease of discussion and illustrative convenience. The techniques and devices discussed with reference to a chip die or a power supply circuit are applicable to any type or number of electrical components (e.g., sensors, transistors, diodes, etc.), circuits (e.g., integrated circuits, analog circuits, digital circuits, mixed circuits, ASICS, memory devices, processors, etc.), groups of components, packaged components, structures, devices, and the like, that may be mounted onto or fully or partially embedded within a carrier, such as a layered printed circuit board (PCB). The previous are collectively referred to as chip dice or IC components. Further, the techniques and devices discussed with reference to discrete components are applicable to any type or number of discrete circuit components (e.g., resistors, capacitors, inductors, chokes, coils, memristors, etc.), groups of components, and the like. These are referred to herein as discrete devices or passive components. Additionally, the techniques and devices discussed with reference to a printed circuit board (PCB) are applicable to other types of carriers (e.g., board, chip, wafer, substrate, package, container, can, module, etc.) that the chip die or other electrical devices may be mounted fully or partially on or within.

Implementations are explained in more detail below using a plurality of examples. Although various implementations and examples are discussed here and below, further implementations and examples may be possible by combining the features and elements of individual implementations and examples.

### Example 3D Packaging Arrangement

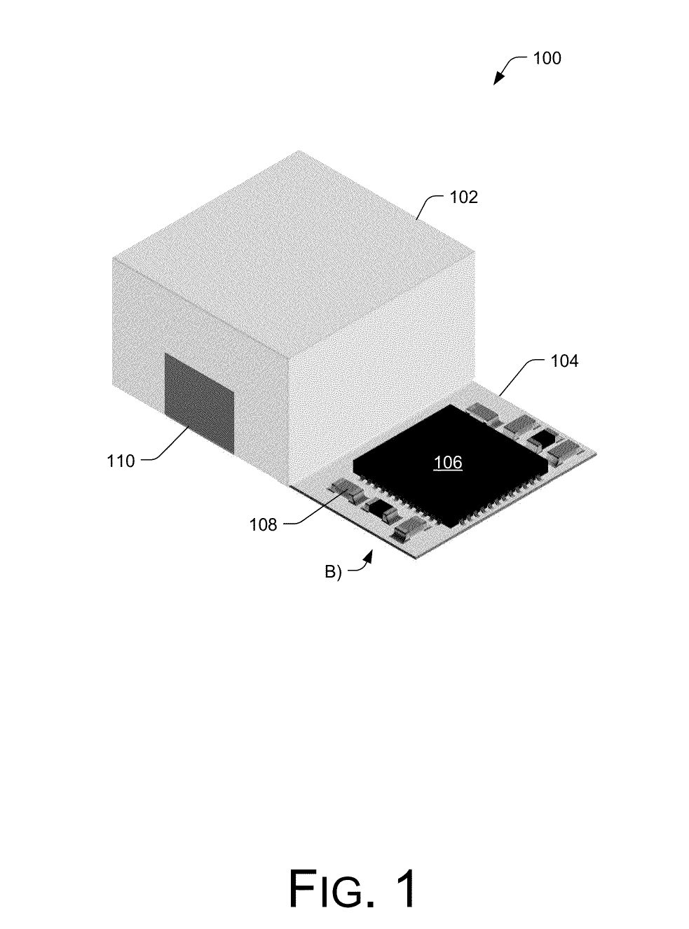

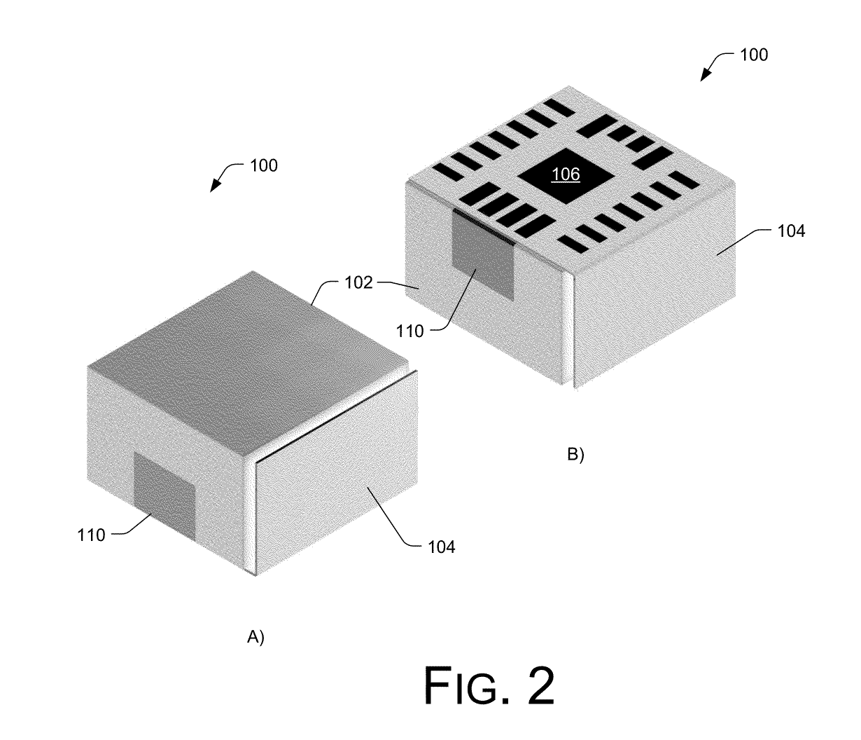

FIG. 1 is a perspective view of an example 3D packaging arrangement 100 including an electrical component (such as a passive component, for example) 102, a PCB 104, an IC chip die 106, and other discrete circuit devices 108, according to an implementation. The illustration of FIG. 1 is shown prior to folding the PCB 104. FIG. 2 illustrates two perspective views of the example 3D packaging arrangement 100 of FIG. 1, after folding the PCB 104, according to an implementation. A topside view A) and an underside view B) are shown.

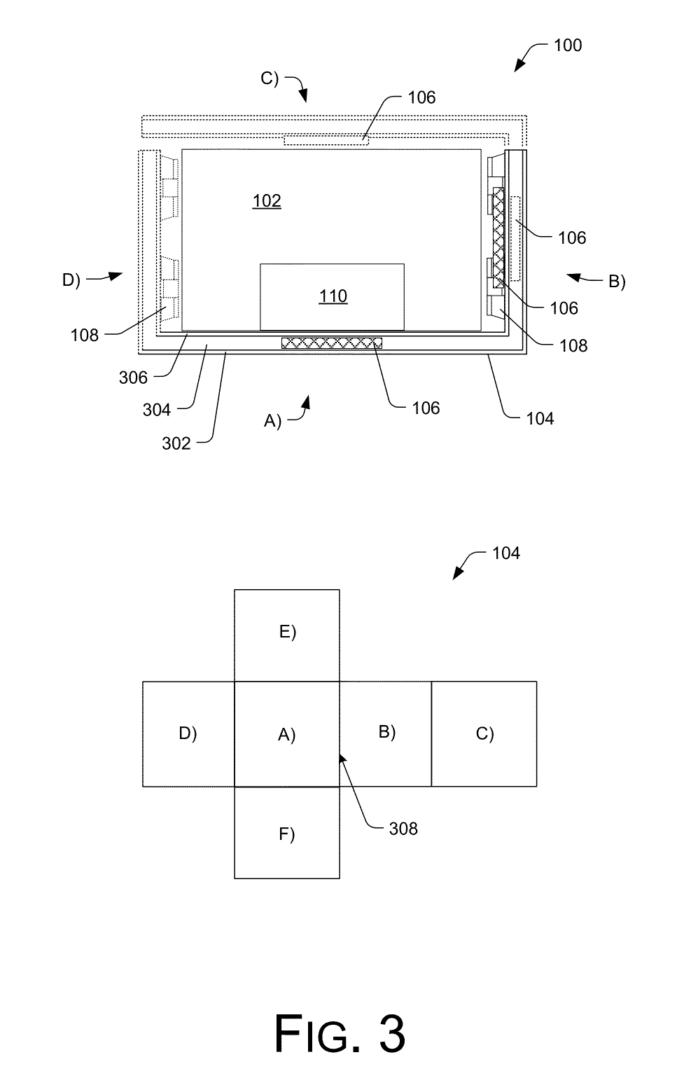

FIG. 3 is a profile view of the example 3D packaging arrangement 100 of FIG. 1, showing example IC components (e.g., chip dice, etc.) 106 and example discrete devices 108 embedded within the PCB 104 and mounted to surfaces of the PCB 104, while the PCB 104 is in a folded configuration, according to an implementation. FIG. 3 also shows an example foldable PCB 104 in a flat (unfolded) configuration, according to an implementation.

The arrangement 100 represents an example environment whereby the techniques and devices discussed herein may be applied. For example, the electrical component 102 is generally representative of a passive device, such as a resistor, a capacitor, an inductor, a transformer, a heat sink, a choke, or the like. Additionally or alternately, the component 102 may be a chassis or enclosure component. In alternate implementations, the component 102 may be an active device, a module, a circuit, a system, or the like. In these and other implementations, the PCB 104 is coupled to the component 102, and is folded to at least partly surround the component 102, such that the footprint of the combination of the component 102 and the PCB 104 is substantially the same area as the footprint of the component 102 alone (as shown in FIGS. 2 and 3). In this way, board area is conserved and additional advantages (e.g., minimized connections, thermal capacitance, etc.) may be realized. In an implementation, the combination of the electrical component 102 and the folded PCB 104 comprises a module, a modular part, or the like.

As shown in FIGS. 1-3, the electrical component 102 may include one or more terminals 110 (e.g., contacts, conductors, leads, etc.). In various implementations, the electrical component 102 may be electrically coupled to the PCB 104, one or more chip dice 106, and/or one or more discrete devices 108 via the terminal(s) 110. For example, in an implementation, the electrical component 102 conducts electrical current as part of an electrical circuit that includes the PCB 104, one or more chip dice 106, and/or one or more discrete devices 108, as discussed further below.

The PCB 104 represents many of various types of carriers (e.g., board, chip, wafer, substrate, package, container, can, etc.) that a chip die 106 or other discrete devices 108 may be mounted fully or partially on or within. In an implementation, the PCB 104 comprises a foldable carrier (i.e., printed circuit board, etc.) arranged to at least partly surround the electrical component 102. In the case where the electrical component 102 has a plurality of non-coplanar outer surfaces, the PCB 104 is arranged to fold at one or more predetermined boundaries, such that two or more portions of the PCB 104 are parallel to two or more respective outer surfaces of the plurality of outer surfaces of the electrical component 102 (as shown in FIGS. 2 and 3). In the context of this disclosure, parallel refers to the plane of each of the first and second portions of the PCB 104 being parallel to the plane of the respective outer surfaces of the electrical component 102. In some implementations, the planes of the portions of the PCB 104 are in close proximity to or are in contact with the planes of the respective surfaces of the electrical component 102.

For example, as shown in FIGS. 1-3, the PCB 104 may include a first portion (portion “A” of FIG. 3, for example) arranged to be coupled to a first outer surface of the electrical component 102, such that the first portion (i.e., the plane of the first portion) of the PCB 104 is parallel to the first outer surface of the electrical component 102. In FIG. 1, the first portion of the PCB 104 is not visible, as it is located underneath the electrical component 102. However, the first portion of the PCB 104 may be seen in the illustrations of FIGS. 2 and 3, and is shown as being coupled to a surface of the electrical component 102 that may often be used to mount the electrical component 102. In an implementation, the first portion of the PCB 104 has an area substantially similar or equivalent to the footprint of the electrical component 102.

In an implementation, as shown in FIGS. 1-3, the PCB 104 may also include a second portion (portion “B” of FIGS. 1 and 3, for example) arranged to be folded such that the second portion (i.e., the plane of the second portion) is parallel to a second outer surface of the electrical component 102. In various implementations, the first outer surface and the second outer surface of the electrical component 102 are non-coplanar surfaces. For example, in the examples illustrated in FIGS. 1-3, the first outer surface and the second outer surface of the electrical component 102 are substantially perpendicular with respect to each other. In such an example, the first portion and the second portion of the PCB 104 are also substantially perpendicular with respect to each other after folding the PCB 104 to conform to the first and second outer surfaces of the electrical component 102. In alternate implementations, the first and second outer surfaces may have any non-coplanar angle with respect to each other.

In one implementation, the first portion and/or the second portion of the PCB 104 are coupled to the respective first and/or second outer surfaces of the electrical component 102. For example, the first portion and/or the second portion may be physically or mechanically coupled to the respective outer surfaces of the electrical component 102. In various implementations, the first portion and/or the second portion may be coupled to the respective outer surfaces of the electrical component 102 via adhesive, fasteners, solder, tabs, clips, and so forth. In alternate implementations, the first portion and/or the second portion may be folded, and remain in a configuration of being substantially parallel to the first and second outer surfaces of the electrical component 102 based on the material properties of the PCB 104.

In an implementation, as shown in FIG. 3, the PCB 104 includes one or more additional portions arranged to be folded such that the one or more additional portions (i.e., the planes of the additional portions) are parallel to one or more additional surfaces of the passive component 102. For example, as shown in FIG. 3, the PCB 104 may include one or more additional portions (portions C, D, E, and/or F, for example) in addition to the first and second portions of the PCB 104. The additional portion(s) may surround one or more surfaces of the electrical component 102, when folded to conform to the outer surfaces of the electrical component 102. In one implementation, the one or more additional portions are coupled to the one or more additional surfaces of the passive component 102, in like manner as described above.

FIG. 3 (lower diagram) shows an example foldable PCB 104 arranged to at least partially surround a rectangular-shaped electrical component 102. If all portions, (A-F) are present, the PCB 104 is arranged to be folded (at the predetermined boundaries 308, for example) to fully surround a rectangular-shaped electrical component 102. However, if less than all of the portions (A-F) are present, the PCB 104 is arranged to be folded to partly surround a rectangular-shaped electrical component 102. This is not intended to be limiting, and in various implementations, a foldable PCB 104 may have different shapes to be arranged to at least partially surround an electrical component 102 having different shaped surfaces, different quantities of surfaces, and the like.

In an implementation, as shown in FIG. 3, the PCB 104 includes a predetermined boundary 308 between the first portion (A) and the second portion (B) of the PCB 104, where the PCB 104 is arranged to be folded. In various implementations, as shown in FIG. 3, the PCB 104 includes multiple predetermined boundaries 308 where the PCB 104 is arranged to be folded in multiple locations. For example, as shown in FIG. 3, in an implementation, the PCB 104 is arranged to fold at least 90 degrees at each of the one or more predetermined boundaries 308. In other implementations. the PCB 104 is arranged to fold other non-zero angles at each of the one or more predetermined boundaries 308.

In one implementation, the PCB 104 includes a metallic trace (not shown) deposited at one or more of the predetermined boundaries, where the metallic trace is arranged to comprise a hinge-line for folding the PCB 104 at the one or more predetermined boundaries 308. For example, a metallic trace may be deposited at or near the line of a predetermined boundary 308, and run the length of the line of the predetermined boundary 308. In one implementation, the metallic trace is positioned at a location that is substantially free from other metallic traces, such as conductors, for example.

As shown in FIG. 3, in an implementation, the PCB 104 is comprised of multiple layers (e.g., 302, 304, and 306). For example, the PCB 104 may have three layers 302, 304, 306, as shown in FIG. 3, or it may be comprised of fewer or more layers 302, 304, 306. In one implementation, the PCB 104 includes a “core” layer 304 located between two or more of the layers 302, 306.

In an implementation, as shown in FIGS. 1-3, the arrangement 100 includes one or more chip dice 106 and/or discrete devices 108 mounted on the PCB 104 and/or embedded in the PCB 104. For example, the one or more chip dice 106 and/or discrete devices 108 may be mounted on and/or embedded within the first (A) and second (B) portions of the PCB 104, as shown in FIGS. 1-3. Alternately or additionally, one or more chip dice 106 and/or discrete devices 108 may be mounted on and/or embedded within the additional portions (C, D, E, F) of the PCB 104, as shown in FIG. 3.

As discussed above, the chip die 106 represents any and all electrical devices that may be located (e.g., partially or fully embedded, etc.) within layers of a PCB 104. For example, a chip die 106 may include an integrated circuit, a logic device, a transistor device, an amplifier device, a controller device, and the like. The discrete devices 108 represent any and all discrete electrical circuit components that may be located on a surface of a layer of the PCB 104. For example, as discussed above, a discrete device 108 may comprise one or more of resistors, capacitors, inductors, chokes, coils, memristors, and the like.

In various implementations, one or more chip dice 106 are located between two layers (302, 304, 306), and may be embedded within the core layer 304, for example. In one implementation, a chip die 106 is located fully within the layers (302, 304, 306) of the PCB 104. In an alternate implementation, the chip die 106 is located partially within the layers (302, 304, 306) of the PCB 104. For example, one or more surfaces of the chip die 106 may be exposed or extend outside of the PCB 104 while the chip die 106 is located partially within the PCB 104.

In various implementations, the chip dice 106 and the discrete devices 108 are part of an electrical circuit that includes the electrical component 102 and the PCB 104. For example, the discrete devices 108 may conduct electrical current (or block or transform current, etc.) as part of an electrical circuit that includes circuit components formed on the chip die 106 and includes the electrical component 102. The electrical current may pass through one or more of the discrete devices 108 as well as through the electrical component 102, and/or portions of the chip die 106, including circuit components or circuits formed on the chip die 106. Accordingly, in an implementation, the PCB 104 includes one or more signal conductors and/or one or more power conductors.

For example, the layout illustrated in FIGS. 1-3 shows an example synchronous-buck circuit design. The architecture of this circuit often consists of a controller, which may control one or more phases of the synchronous-buck circuit. Each phase may consist of a driver IC, a pair of power semiconductor devices (high-side and low-side), an LC circuit consisting of a large inductor and one or more output capacitors, a number of passives (resistors and capacitors) used to stabilize and trim the circuit.

The chip dice 106 are represented by the controller, driver IC, and low and high side transistors (e.g., field-effect transistors (FET), etc.), for example. The discrete devices 108 are represented by circuit components such as resistors, inductors, and capacitors, for example. The electrical component 102 is represented by an output inductor, for example, of the synchronous-buck circuit. In various implementations, the electrical component 102 may comprise different portions of an electrical circuit including the PCB 104, chip dice 106, and/or discrete devices 108.

The techniques, components, and devices described herein with respect to the arrangement 100 are not limited to the illustrations in FIGS. 1-3, and may be applied to other designs, types, arrangements, and constructions including other electrical components without departing from the scope of the disclosure. In some cases, alternative components may be used to implement the techniques described herein. In various implementations, the arrangement 100 may be a stand-alone module, or it may be a portion of a system, component, structure, or the like.

### Example Implementations

In an implementation, a circuit (such as the synchronous-buck circuit design shown in FIGS. 1-3, for example) is designed and laid out on a multi-layer PCB 104 for optimized performance of the circuit elements, including optimized thermal performance. For example, the circuit is designed and laid out such that the circuit elements have optimized speed of operation, impedance characteristics, functional characteristics, power consumption profiles, parasitic performance, longevity, and the like, and also provide optimized management of heat generated by the circuit elements (and particularly the chip dice 106). In one implementation, the circuit does not make use of conventional heat sinks (e.g., heat sinks that are not part of current path(s), etc.).

In an implementation, as shown in FIGS. 1-3, the placement of the passive electrical component(s) 102 with respect to the chip dice 106 provides optimized performance (e.g., power efficiency, speed, etc.) of the circuit, based on optimized conductor paths (e.g., minimal length, preferred path, low impedance coupling, etc.). For example, in an implementation, a conductor lead of at least one of the chip dice 106 and/or one or more of the discrete devices 108 is arranged to be electrically coupled to a conductor lead (e.g., terminal) 110 of the passive electrical component 102.

In the example of the synchronous-buck circuit design, power semiconductor devices (e.g., chip dice 106, etc.) can be mounted between the power input contacts (Vin & GND) of the circuit, and the other side of the semiconductors 106 can be connected to a terminal of the inductor (passive electrical component 102). This can result in the semiconductor devices 106 being in a vertical conduction path, which in turn can result in significant reductions in stray parasitic losses.

Additionally, embedding of the chip dice 106 in a circuit with direct plated contacts can reduce losses in thermal and electrical performance associated with intermetallic formations and or interfacial resistance of other connection mediums. Further, a metalized layer of the semiconductor device 106 may be connected via solder joints, for example, to a lead 110 of the inductor 102 and the metallic pads of the PCB 104. In this arrangement, thermal conductance and capacitance may be improved by the connectivity of the circuits and the need for additional heat-sinking can be avoided.

In alternate implementations, one passive component 102 (such as an inductor, for example) may be included in an arrangement 100, where the passive component 102 is strategically located on an outer surface of one of the layers (302, 306) of the PCB 104, or multiple passive components 102 may be included in an arrangement 100, where the passive components 102 are strategically located on the outer surface of either or any layer 302, 306 of the PCB 104. For example, one or more passive components 102 may be located on each of the layers 302, 306 of the PCB 104, or located on one or more of the layers 302, 306 of a multi-layer PCB 104.

In the implementation, the passive electrical component 102 is strategically located and arranged to conduct heat generated by one or more of the chip dice 106 and/or one or more of the discrete devices 108 away from the respective one or more of the chip dice 106 and/or the one or more discrete devices 108. The proximity of the passive electrical component 102 allows heat generated by the chip die 106 to be thermally conducted to the passive component 102 either by direct contact or through thermal capacitance, and dissipated into the environment. For example, as shown in FIGS. 1-3, the passive component 102 may be deliberately or strategically placed above or below the chip dice 106.

In an implementation, the surface area and/or mass of the passive component 102 aids in dissipating heat to the environment. In various implementations, the greater the surface area and/or mass of a passive component 102, the greater the heat dissipation capability of the passive component 102.

In various implementations, the PCB 104 may have alternate constructions. For example, in one implementation, the PCB 104 comprises an ultra-thin laminate, with a core thickness of approximately 50 microns (plus or minus 10 microns, for example). In an implementation, the core may be relatively flexible, but may also gain significant rigidity from the metallic layers that are deposited on the surface. In some implementations, the core material may differ slightly from a common laminate core, having some differences in glass weaves, copper hardness, resin types, and/or the like, to improve the bending of the PCB 104.

In an implementation, metallic tracks that connect internally to the chip dice 106 and/or the discrete devices 108 are included on or within layers of the PCB 104. Accordingly, when the PCB 104 is folded, a number of conductor tracks are bent around the bends in the PCB 104. In general these tracks may be signal tracks, and so may not have a substantial metallic cross-sectional area. In various implementations, the tracks can be on both sides of the layers of the PCB 104. However, as mentioned above, to aid the bending of the PCB 104, areas that are relatively clear of tracks may have metallic traces deposited in a way to create a hinge-point along the bend-lines (much like placing a rule on a sheet of paper to form a sharp bend line).

Different configurations for an arrangement 100 may be possible with different implementations. In alternate implementations, various other combinations and designs of the arrangement 100 are also within the scope of the disclosure. The variations may have fewer elements than illustrated in the examples shown in FIGS. 1-4, or they may have more or alternative elements than those shown.

### Representative Process

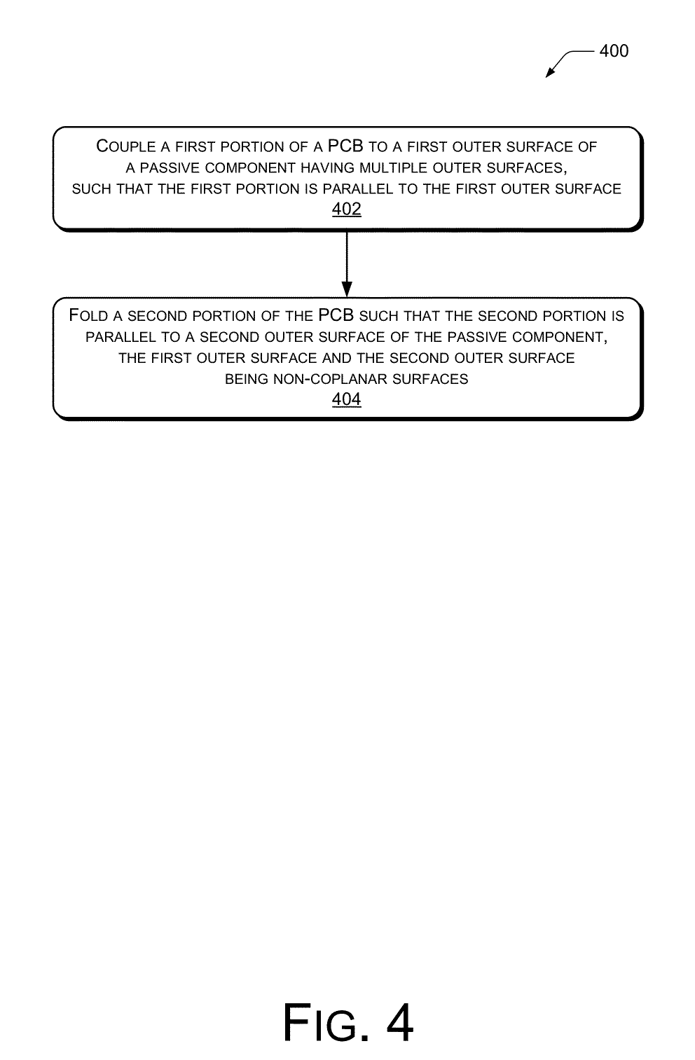

FIG. 4 illustrates a representative process 400 for optimizing board area using three dimensional packaging techniques. For example, a carrier (such as PCB 104, for example) with components (such as chip dice 106 and/or discrete devices 108, for example) mounted thereon and/or embedded therein may be folded to at least partly surround an electrical component (such as electrical component 102, for example). The process 400 is described with reference to FIGS. 1-3.

The order in which the process is described is not intended to be construed as a limitation, and any number of the described process blocks can be combined in any order to implement the process, or alternate processes. Additionally, individual blocks may be deleted from the process without departing from the spirit and scope of the subject matter described herein. Furthermore, the process can be implemented in any suitable materials, or combinations thereof, without departing from the scope of the subject matter described herein.

At block 402, the process includes coupling a first portion of a printed circuit board (PCB) (such as PCB 104, for example) to a first outer surface of a passive component (such as electrical component 102, for example) having multiple outer surfaces, such that the first portion is parallel to the first outer surface. In various implementations, the process includes coupling the first portion of the PCB to the first outer surface.

At block 404, the process includes folding a second portion of the PCB such that the second portion is parallel to a second outer surface of the passive component. In an implementation, the first outer surface and the second outer surface are non-coplanar surfaces. In various implementations, the process includes coupling the second portion of the PCB to the second outer surface.

In various implementations, the first portion and/or the second portion may be coupled to the respective outer surfaces of the passive electrical component via adhesive, fasteners, solder, tabs, clips, and so forth. In alternate implementations, the first portion and/or the second portion may be folded, and remain in a configuration of being substantially parallel to the first and second outer surfaces of the electrical component based on the material properties of the PCB.

In an implementation, the process includes folding one or more additional portions of the PCB such that the one or more additional portions are parallel to respective one or more additional outer surfaces of the passive component.

In an implementation, the process includes mounting one or more electrical components (such as chip dice 106 and/or discrete devices 108, for example) to the first portion and/or the second portion of the PCB and/or embedding one or more electrical components (such as chip dice 106 and/or discrete devices 108, for example) within layers of the first portion and/or within layers of the second portion of the PCB.

In another implementation, the process includes strategically locating the passive component with respect to an outer surface of a layer of the PCB. In various implementations, the PCB may have any number of layers. In one example, the process includes arranging one or more of the electrical components with respect to the passive component such that the passive component conducts heat generated by the one or more of the electrical components away from the one or more of the electrical components.

In a further implementation, the process includes aligning one or more of the electrical components with respect to the passive component such that a conduction path length between the one or more of the electrical components and the passive component is minimized.

In various implementations, the various components (including the passive component) may be coupled to a layer of the PCB using various techniques (e.g., soldering, press-fit, connectors, surface mount technologies, through-hole technology, and so forth).

In various implementations, the passive component is selected from a set comprising: resistors, capacitors, inductors, transformers, chokes, heat sinks, and the like. In alternate implementations, the passive components may be comprised of other devices, elements, circuits, and the like.

In alternate implementations, other techniques may be included in the process 400 in various combinations, and remain within the scope of the disclosure.

### Conclusion

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

What is claimed is:

1. An apparatus, comprising:
a foldable printed circuit board (PCB) arranged to at least partly surround an electrical component having a plurality of non-coplanar outer surfaces, the PCB arranged to fold at one or more predetermined boundaries, such that two or more portions of the PCB are parallel to two or more respective outer surfaces of the plurality of outer surfaces of the electrical component.

2. The apparatus of claim 1, the PCB further including one or more electrical devices mounted thereon and/or one or more other electrical devices embedded therein.

3. The apparatus of claim 2, wherein at least one of the one or more electrical devices and/or the one or more other electrical devices comprises an integrated circuit (IC) chip die.

4. The apparatus of claim 1, the PCB further including a plurality of layers.

5. The apparatus of claim 1, the PCB further including one or more signal conductors and/or one or more power conductors.

6. The apparatus of claim 1, the PCB further comprising a metallic trace deposited at one or more of the predetermined boundaries, the metallic trace arranged to comprise a hinge-line for folding the PCB at the one or more predetermined boundaries.

7. The apparatus of claim 1, wherein the two or more portions of the PCB are coupled to the two or more respective outer surfaces of the electrical component.

8. The apparatus of claim 1, wherein the electrical component conducts electrical current as part of an electrical circuit that includes the PCB.

9. The apparatus of claim 1, wherein the PCB is arranged to fold at least 90 degrees at each of the one or more predetermined boundaries.

10. An electronic module, comprising:
a passive component having multiple outer surfaces; and
a printed circuit board (PCB) having a first portion arranged to be coupled to a first outer surface of the passive component such that the first portion is parallel to the first outer surface and a second portion arranged to be folded such that the second portion is parallel to a second outer surface of the passive component, the first outer surface and the second outer surface being non-coplanar surfaces.

11. The electronic module of claim 10, further comprising a predetermined boundary between the first portion and second portion of the PCB, wherein the PCB is arranged to be folded at the predetermined boundary.

12. The electronic module of claim 10, the first portion and/or the second portion further including one or more electrical components mounted thereon and/or one or more other electrical components embedded therein, the passive component and the one or more electrical components and/or the one or more other electrical components forming at least a portion of an electrical circuit.

13. The electronic module of claim 12, wherein the passive component is strategically located and arranged to conduct heat generated by one or more of the electrical components and/or one or more of the other electrical components away from the respective one or more of the electrical components and/or the one or more of the other electrical components.

14. The electronic module of claim 12, wherein a conductor lead of at least one of the one or more electrical components and/or one or more other electrical components is arranged to be electrically coupled to a conductor lead of the passive component.

15. The electronic module of claim 10, the PCB further including one or more additional portions arranged to be folded such that the one or more additional portions are parallel to one or more additional surfaces of the passive component.

16. The electronic module of claim 15, wherein the one or more additional portions are coupled to the one or more additional surfaces of the passive component.

17. The electronic module of claim 15 wherein the one or more additional portions include one or more electrical components mounted thereon and/or one or more other electrical components embedded therein.

18. The electronic module of claim 10, wherein the passive component comprises one of a resistor, a capacitor, an inductor, a transformer, a heat sink, and a choke.

19. A method, comprising:
coupling a first portion of a printed circuit board (PCB) to a first outer surface of a passive component having multiple outer surfaces, such that the first portion is parallel to the first outer surface; and
folding a second portion of the PCB such that the second portion is parallel to a second outer surface of the passive component, the first outer surface and the second outer surface being non-coplanar surfaces.

20. The method of claim 19, further comprising coupling the second portion of the PCB to the second outer surface.

21. The method of claim 19, further comprising folding one or more additional portions of the PCB such that the one or more additional portions are parallel to respective one or more additional outer surfaces of the passive component.

22. The method of claim 19, further comprising mounting one or more electrical components to the first portion and/or the second portion of the PCB and/or embedding one or more electrical components within layers of the first portion and/or within layers of the second portion of the PCB.

23. The method of claim 22, further comprising arranging one or more of the electrical components with respect to the passive component such that the passive component conducts heat generated by the one or more of the electrical components away from the one or more of the electrical components.

24. The method of claim 22, further comprising aligning one or more of the electrical components with respect to the passive component such that a conduction path length between the one or more of the electrical components and the passive component is minimized.

25. A system, comprising:
a multi-layer printed circuit board (PCB) including a plurality of layers;
a plurality of electrical components embedded within layers of the PCB and/or mounted to one or more of the plurality of layers of the PCB; and
a passive circuit component strategically coupled to a first portion and a second portion of one of the plurality of layers of the PCB such that a first surface of the passive circuit component is parallel to the first portion and a second surface of the passive circuit component is parallel to the second portion, the first surface and the second surface being non-coplanar.
